(19) United States
(12) Patent Application Publication
(10) Pub. No.: US 2002/0068381 A1
(43) Pub. Date: Jun. 6, 2002

(54) Ultra-fine contact alignment

(75) Inventors: Thomas G. Ference, Essex Junction, VT (US); Wayne J. Howell, Williston, VT (US)

Correspondence Address: Connolly Bove Lodge & Hutz LLP, Suite 800, 1990 M Street, N.W., Washington, DC, 20036-3425, US

(73) Assignee: International Business Machines Corporation, Armonk, NY

(21) Appl. No.: 09/985,693

(22) Filed: Nov. 5, 2001

Related U.S. Application Data
(62) Division of application No. 09/261,328, filed on Mar. 3, 1999.

(51) Int. Cl. H01L 23/488

(52) U.S. Cl. 438/108; 29/840

(57) ABSTRACT

A semiconductor structure including a first substrate and a second substrate joined to the first substrate. A plurality of contacts extend between the first substrate and the second substrate. A plurality of first solder bumps are connected between the first substrate and the second substrate for aligning the contacts.

### FIELD OF THE INVENTION

The invention relates to a structure for joining two substrates in a semiconductor structure. The present invention also relates to a method for joining two substrates.

### BACKGROUND OF THE INVENTION

In making semiconductor device structures, often, two smaller structures are joined to form an overall larger structure or one portion of an even larger structure. Examples include two semiconductor chips joined together and a semiconductor chip joined to a structure such as a chip support or lead frame. One structure and method that utilizes the structure for joining together two smaller structures to form a larger semiconductor device includes providing a plurality of soldered connections between the two smaller structures.

One particular method for joining together two semiconductor structures is referred to as a controlled collapse chip connection or “C4”. A C4 includes providing a plurality of balls or bumps of solder between the two structures. The solder balls or bumps may be attached to portions of wiring elements on each chip. According to such processes, a seed layer may be patterned, followed by lead-tin plating.

C4 connections have self-aligning capabilities to ensure proper alignment of the two structures joined. The self-aligning capabilities result from surface tension inherent in the solder in the C4 connections. The solder will adhere to connecting elements, such as pads, on the two structures being joined. the surface tension will draw the two structures together and align the connecting elements the solder attaches to.

Typical dual chip I/O band widths are limited by the size and pitch of C4 interconnections that can be created and reliably joined between two chips. The current standard for C4 interconnects includes C4 connections having a diameter of about 100 μm having a pitch of about 225 μm. For a chip having an area of about 1 cm², this can provide about 2,000 interconnects.

Another method and structure utilized for interconnecting two semiconductor substrates is typically known as polymer metal composite (PMC). As the name suggests, PMC connections typically include a composite material that includes polymeric elements and metallic elements necessary to achieve an electrical and mechanical connection.

### SUMMARY OF THE INVENTION

The present invention provides a structure and process for reliably making very small interconnects between two semiconductor substrates. The present invention may be utilized along or in combination with other alignment structures.

The present invention provides a semiconductor structure including a first substrate and a second substrate joined to the first substrate. A plurality of contacts are arranged between the first substrate and the second substrate. A plurality of first solder bumps are connected between the first substrate and the second substrate for aligning the contacts.

The present invention also provides a method of fabricating a semiconductor structure. The method includes providing a first substrate and a second substrate. Contacts are provided on one of the first substrate and the second substrate. First solder bumps are provided on one of the first substrate and the second substrate. The first substrate and the second substrate are joined together. The first solder bumps are then reflowed for surface tension aligning of the contacts.

Still other objects and advantages of the present invention will become readily apparent by those skilled in the art from the following detailed description, wherein it is shown and described only the preferred embodiments of the invention, simply by way of illustration of the best mode contemplated of carrying out the invention. As will be realized, the invention is capable of other and different embodiments, and its several details are capable of modifications in various obvious respects, without departing from the invention. Accordingly, the drawings and description are to be regarded as illustrative in nature and not as restrictive.

### BRIEF DESCRIPTION OF THE DRAWINGS

The above-mentioned objects and advantages of the present invention will be more clearly understood when considered in conjunction with the accompanying drawings, in which:

FIGS. 1a, 1b, and 1c represent x-ray views of two substrates at various stages in the process of rough and fine alignment by solder bumps and contacts according to the present invention;

FIG. 2 represents a surface view of an embodiment of a structure according to the present invention;

FIG. 3 represents a cross-sectional view of one embodiment of the present invention illustrating solder contacts and bumps prior to contact reflow and subsequent to solder bump reflow;

FIG. 4 represents a cross-sectional view of the structure illustrated in FIG. 3, subsequent to reflow of the contacts;

FIG. 5 represents a cross-sectional view of another embodiment of the present invention including contacts made from a material other than solder and including solder alignment bumps prior to reflow of the solder bumps;

FIG. 6 represents a cross-sectional view of the structure illustrated in FIG. 5 after reflow of the solder bumps;

FIG. 7a illustrates a cross-sectional view of a further embodiment of a structure according to the present invention including solder and dendritic contacts and solder alignment bumps prior to reflow of the solder;

FIG. 7b represents a cross-sectional view of the structure illustrated in FIG. 7a following reflow of the solder;

FIG. 8a represents a cross-sectional view of yet another embodiment of the present invention that includes solder contacts and solder bumps before reflow of the solder;

FIG. 8b represents a cross-sectional view of the structure illustrated in FIG. 8a subsequent to solder bump reflow;

FIG. 8c represents a cross-sectional view of the structure illustrated in FIGS. 8a and 8b after reflow of the contacts; and

FIGS. 9a, 9b, 9c, and 9d illustrate cross-sectional views of a structure at various stages of an embodiment of a process according to the present invention for forming an embodiment of an interconnect structure according to the present invention.

### DETAILED DESCRIPTION OF THE INVENTION

Currently, the limit of C4 interconnection technology includes arrays of C4 connections having a diameter of about 50 μm on a pitch of about 100 μm. Based on this limit, for a chip having an area of about 1 cm², one can have at most about 10,000 C4 interconnects. The present invention addresses this issue by providing a method of making a structure and a structure that results in a much greater numbers of interconnects compared with current C4 technology.

Another issue related to the above-described interconnect structure relates to the lack of self-aligning capabilities of PMC connections as compared to solder connections. This limits the ability to make very small well aligned interconnects utilizing PMC.

The present invention provides an interconnection structure and method of fabricating the interconnection structure that permits a much greater number of interconnections to be formed between two substrates, such as semiconductor chips, as compared to existing structures and processes. The interconnections of the present invention are smaller and may be made in a much greater density than known interconnection structures. Along these lines, while currently known technology may possibly result in forming up to about 10,000 interconnects per square centimeter, the present invention may be utilized to form over 100,000 interconnects per square centimeter between two chips. Another advantage of the present invention is that it facilitates extremely high I/O band width communication between chips.

In general, the present invention provides semiconductor structure including a first substrate and a second substrate joined to the first substrate. A plurality of contacts exist between the first substrate and the second substrate. The structure also includes a plurality of first solder bumps connected between the first substrate and a second substrate for aligning the contacts.

At least one of the first substrate and the second substrate may be an integrated circuit chip. In fact, both the first substrate and the second substrate may be integrated circuit chips. However, one or both of the first substrate and second substrate could be a structure other than a semiconductor chip. For example, one of the first substrate and the second substrate could be a semiconductor chip and the other a chip support, lead frame or other such structure.

The first solder bumps help to align the two structures such that the contacts will align between the desired interconnection points on each substrate. Typically, the first solder bumps are larger than the contacts. Making the first solder bumps larger than the contacts may help to maintain the two substrates separated at a distance sufficient to prevent contact of both substrates by the contacts prior to alignment of the two substrates by the first solder bumps.

A key inventive concept of this invention is the use of larger solder bumps which when connecting two semiconductor structures deliver the high precision alignment necessary to achieve the interconnection of the much smaller contacts. This solder bump pre-alignment allows the use of significantly smaller contacts placed on a much finer pitch, thereby enabling a substantially higher contact interconnection densities than that possible without the use of the solder bumps.

The contacts may be smaller than the first solder bumps. Typically, for example, the contacts may have a size, measured by diameter, as small as about 20% of the diameter of the first solder bumps.

The first solder bumps accomplish a rough self-alignment of two substrates. To achieve this, not only may the first solder bumps be larger, but they may have a composition such that they melt at a lower temperature than the contacts, if the contacts are made of solder. Examples of materials that may be utilized to form the contacts include 90:10-97:3 lead:tin solder. In other words, solder that is from about 90% lead and about 10% tin to about 97% lead and about 3% solder. On the other hand, the solder bumps may be formed from eutectic lead/tin solder have a composition of about 37% lead and about 63% tin, having a eutectic temperature about 183 degrees Celsius. Additionally, non-Pb-based solders may also be used for this invention.

In order to achieve the fine alignment necessary for the acceptable contact interconnection, typically the contacts should be aligned to within about 50% of their diameter. This may achieved by utilizing the rough alignment capabilities of the solder bumps. Reflow of the solder bumps may align the two substrates to within about 10% of the solder bump diameter.

For a contact density of about 100,000 contacts/cm², one would have an approximately 15 μm diameter on approximately a 30μm pitch. To arrive within about 50% alignment of the contact, one would need 7.5μm alignment tolerance from the rough align solder bumps. Hence, with the approximate 10% alignment capabilities of the rough align solder bumps one could use about 75μm diameter solder bumps on a 150μm pitch, this is well within the current technology limits.

This approximate 5× contact-to-rough align diameter can be used as a design metric. However, one may vary from this. Table 1 below presents some estimated contact densities achievable for various rough alignment solder bump diameters.

TABLE 1

| Solder Bump | Contact | Contact |
|---|---|---|
| Diameter (μm) | Diameter (μm) | Density/cm² |
| 100 | 20 | 60,000 |
| 75 | 15 | 100,000 |
| 50 | 10 | 250,000 |

The contacts of the present invention may be made of solder or other materials. If the contacts are made of solder, they may permit fine alignment of the two substrates being connected. Along these lines, fine alignment is considered herein typically to be within 10% of the solder bump diameter.

If the contacts are made of solder they have a smaller diameter than the first solder bumps. However, because there are many more contacts than first solder bumps, the total interconnection surface area for the contacts exceeds that for the first solder bumps.

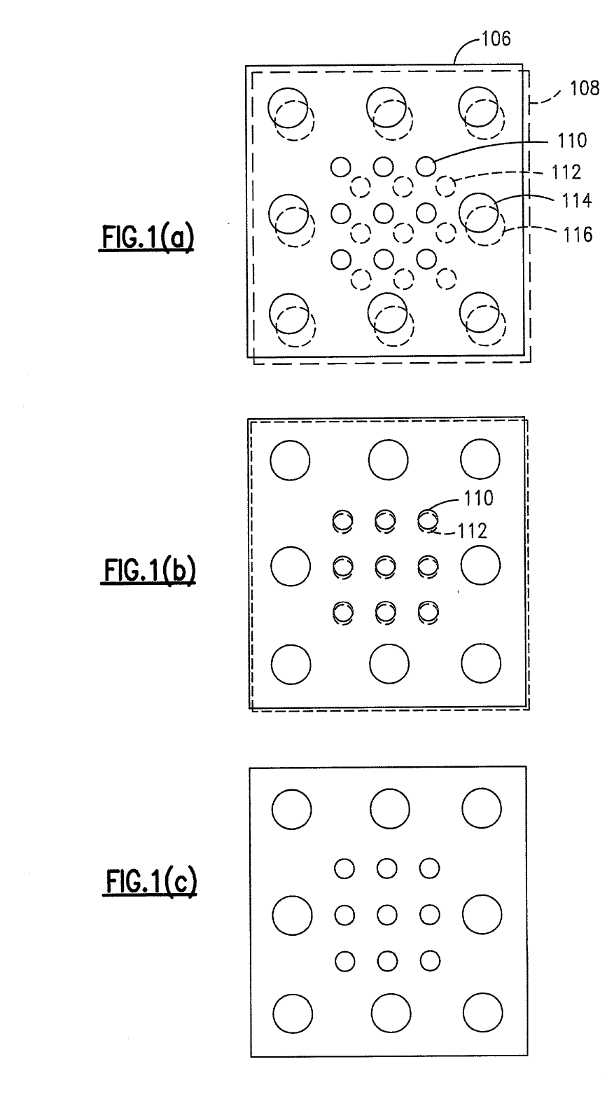

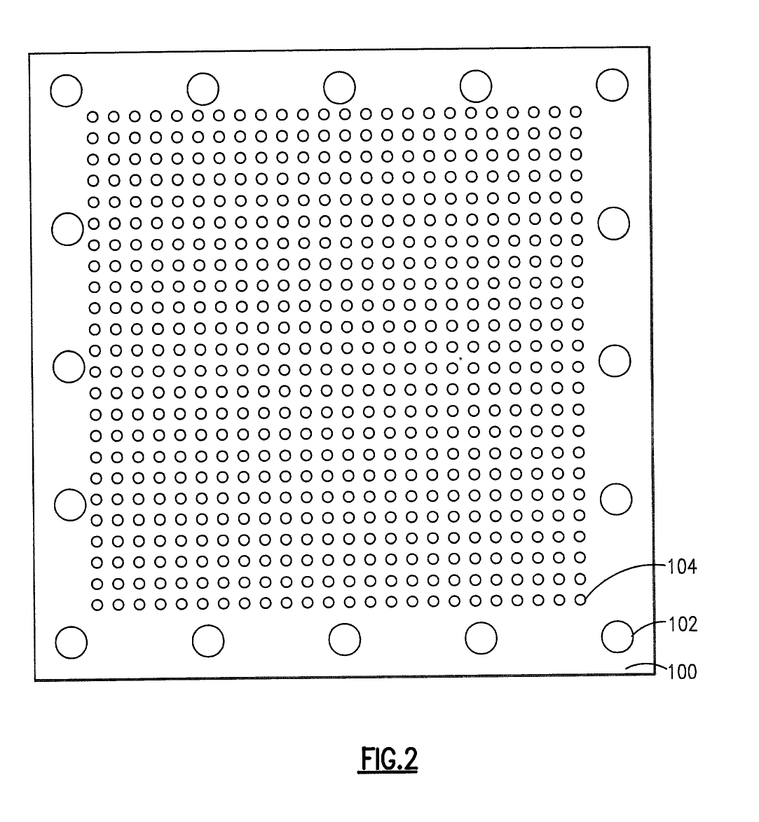

FIGS. 1a-c illustrate two substrates at various stages of a method for fabricating a semiconductor structure according to the present invention utilizing an embodiment of a contact and solder bump structure according to the present invention. Along these lines, FIG. 1a shows the substrates 106 and 108 after provision of the contacts 110, contact pads 112 and solder bumps 114, solder bump pads 116 and mounting the substrates on each other. At the stage FIG. 1 illustrates, the locations to joined by the solder bumps and the contacts are out of alignment. FIG. 1b represents the substrates upon melting of the solder bumps and rough alignment of the substrates. As can be seen from FIG. 1b, rough alignment of the solder bumps has brought the contact pads 112 into greater alignment with the contacts 110. As the contacts melt, fine alignment of the substrates being joined will be achieved, as illustrated in FIG. 1c.

Typically, to help ensure that the two structures being joined together are roughly aligned prior to the contacts contacting both structures, the contacts, if they are solder, have a higher melting point than the first solder bumps. This will permit the solder of the rough align solder bumps to first melt and roughly align the two substrates, as represented in FIG. 1b. Then, the temperature may be raised, causing the contacts to melt, resulting in further alignment of the two substrates, and forming a connection between the two substrates, as shown in FIG. 1c. Additional fine alignment is achieved because the total area of the contacts is greater than the area of the rough align solder bumps.

FIG. 2 illustrates an example of a grid arrangement of the contacts and solder bumps according the present invention. Of course, this represents only one example of a layout for the contacts and rough align solder bumps. Other patterns can work as well.

The structure illustrated in FIG. 2 includes a substrate 100 with first solder bumps 102 and contacts 104 arranged thereon. In the embodiment illustrated in FIG. 2, the contacts 104 occupy about 35% more interconnection surface area of the substrate 100 than the first solder bumps 102. Also in this embodiment, the diameter of each contact is about one-fifth of the diameter of each first solder bump.

According to other embodiments, rather than being formed of solder, the contacts may comprise electrically conductive epoxy. The contacts may also comprise a polymer-metal composite. Examples of epoxies and composites that may be utilized include, respectively, Epo-tech, available from Epoxy Technology, Inc. and PMC paste, a polymer metal composite paste.

Additionally, the interconnect technology for the contacts is not limited to those mentioned above. Other examples include dendrites and self-interlocking micro connectors. These are discussed in greater detail in U.S. Pat. No. 5,818,748, the entire contents of the disclosure of which is hereby incorporated by reference.

By utilizing the rough aligned first solder bumps in combination with interconnect methods other than solder, the present invention may permit finer pitch interconnection structures to be formed with these alternate interconnection methods that is otherwise known.

An example of the present invention is illustrated in FIG. 3, which represents a cross-sectional view of an embodiment of a structure according to the present invention prior to reflow of the contacts and the first solder bumps. The structure illustrated in FIG. 3 is for joining two integrated circuit chips 1 and 3. Integrated circuit chips 1 and 3 include interconnection pads 9 and interconnection pads 11, respectively, for connection to the contacts. Integrated circuit chips 1 and 3 also include interconnection pads 13 and interconnection pads 15, respectively, for connection to first solder bumps.

The structure includes first solder bumps 5 and contacts 7. The contacts in the embodiment illustrated in FIG. 3 are formed of solder. The contacts are arranged on integrated circuit chip 3 over interconnection pads 9. When the structure of the present invention is formed, the contact 7 will provide interconnection between interconnection pads 9 and contact pads 11 on integrated circuit chips 1 and 3, respectively. First solder bumps 5 may be connected between interconnection pads 13 on integrated circuit chip 3 and interconnection pads 15 on integrated circuit chip 1.

FIG. 3 also illustrates an additional aspect of that may be included in embodiments of the present invention. According this aspect, the surface of one of the integrated circuit chips may include surfaces arranged at different levels. Along these lines, the upper surface of integrated circuit chip 3 includes a level 17 where interconnection pads 13 may be provided and first solder bumps 5 may contact. The upper surface of integrated circuit chip 3 also includes a second level 19 where interconnection pads 9 may be provided and contact 7 may be arranged on. On the other hand, the lower surface of integrated circuit chip 1 may be arranged at one level, or at least a portion that is illustrated in FIG. 3 and is involved in the contact structure of the present invention may be arranged in a single level. The ledge illustrated in FIG. 3 on integrated circuit chip 3 also helps to ensure that one side of both the first solder bumps and the contacts will be in the same plane.

According to another embodiment, the upper surface of the lower substrate may be one co-planar surface, while the lower surface of the upper substrate may be arranged in more than one surface.

By providing a substrate, such as an integrated circuit chip, that includes a surface and at least two planes, the present invention can accommodate larger first solder bumps 5 as illustrated in FIG. 3. In such an embodiment, the first solder bumps need only collapse to an extent such that the smaller space between surface 19 of integrated circuit chip 3 and surface 21 of integrated circuit chip 21 will approach each other such that contact 7 can make a connection between the two chips. Contacts 7 may be made smaller than solder bumps 5. Providing a two level upper surface of chip 3 can help to reduce the amount that first solder bumps 5 need to collapse.

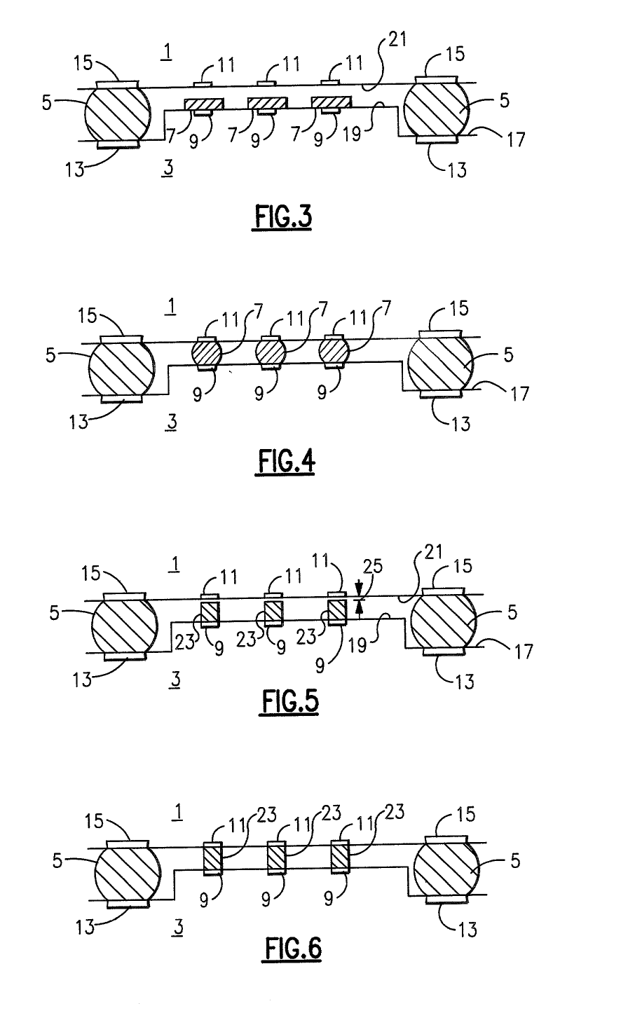

FIG. 4 illustrates a cross-sectional view of the structure illustrated in FIG. 3 after reflow of the solder making up both the first solder bumps 5 and contacts 7 illustrating the final form of the C4 connection according to the present invention.

FIG. 5 illustrates a cross-sectional view of an embodiment of the present invention that includes contacts 23 that are made of a material other than solder. For example, the contacts 23 illustrated in FIG. 5 could be made of a polymer metal composite.

For purposes of clarity, these structures illustrated in FIG. 5 other than contacts 23, have the same numbering as in the structures illustrated in FIGS. 3 and 4. Accordingly, FIG. 5 illustrates integrated circuit chips 1 and 3. Integrated circuit chip 3 includes interconnection pads 9 and 13, while integrated circuit chip 1 includes contact pads 11 and 15.

FIG. 5 illustrates the structure prior to reflow of first solder bumps 5. At this time, a gap 25 exists between the upper surface of contacts 23 and the lower surface 21 of integrated circuit chip 1. FIG. 6 illustrates a cross-sectional view of the structure illustrated in FIG. 5 after collapse of solder bumps 5. In the structure illustrated in FIG. 6, contacts 9 have been compressed by collapse of the solder bumps 5. Interconnection pads 9 and 11 have also been aligned by collapse of first solder bumps 5.

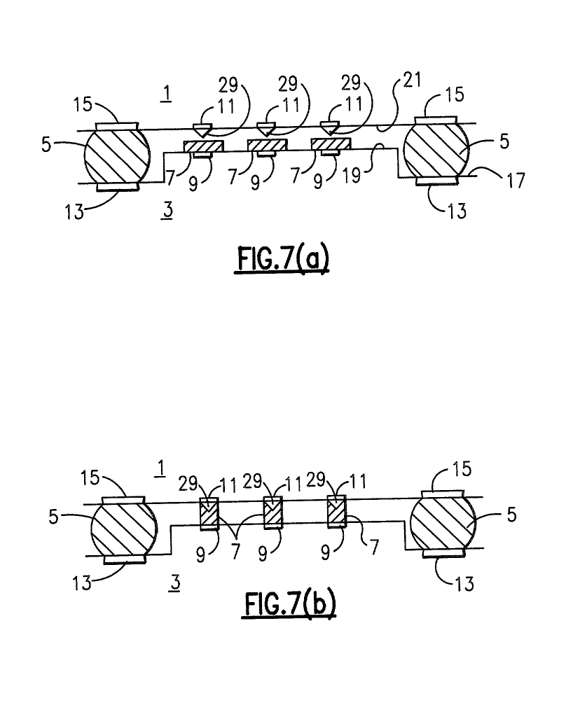

FIG. 7a illustrates a further embodiment of the structure according to the present invention. Again, for purposes of clarity, structures in FIG. 7a similar to structures in the embodiments illustrated in FIGS. 3-6 retain similar numbering. The structure illustrated in FIG. 7a is similar to the structure illustrated in FIG. 3, with the exception that a dendrite 29 is attached to each interconnection pads 11 on integrated circuit chip 1. FIG. 7a illustrates the device prior to solder reflow.

FIG. 7b illustrates the structure illustrated in FIG. 7a after reflow of the first solder bumps 5 and the contacts 7. As the integrated circuit chip 1 moves toward integrated circuit chip 3 as solder bumps 5 reflow and collapse, dendrites 29 will contact solder 7. As in the other embodiments, service tension will help to achieve fine alignment of the structures. However, dendrites 29 may enhance the alignment by providing additional surface area for the contacts 7 to engage. The dendrites may also provide a structure that extends down into the solder contacts 7.

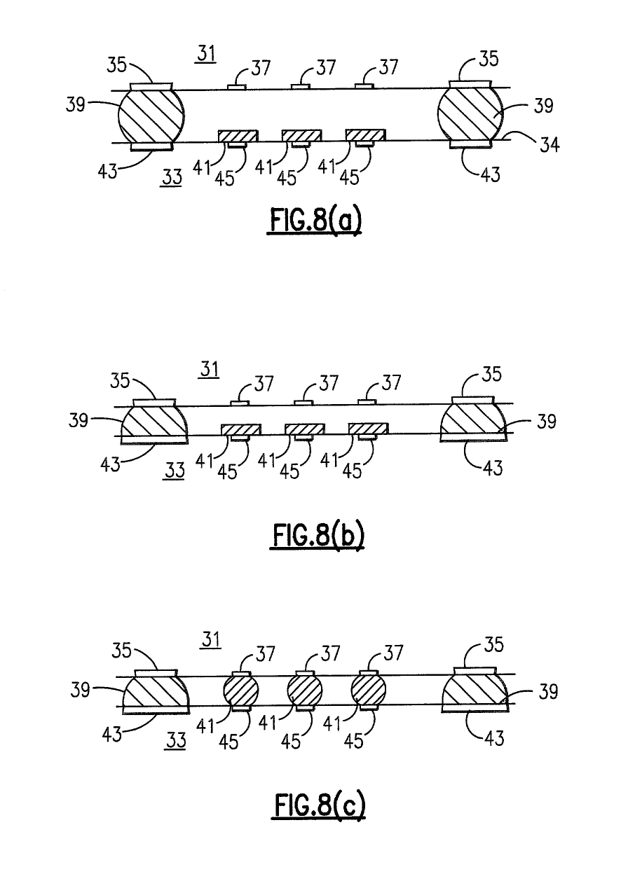

FIGS. 8a-8c illustrate an embodiment of the present invention similar to the embodiment illustrated in FIGS. 3 and 4. However, the embodiment illustrated in FIGS. 8a-8c does not include a substrate that includes a surface at two different levels. Due to the differences between the embodiments illustrated in FIGS. 3 and 4 and the embodiment illustrated in FIGS. 8a-8c, all of the structures have been renumbered.

Along these lines, FIGS. 8a-8c illustrate two substrates 31 and 33. Substrate 31 includes interconnection pads 35 and 37 for interconnecting, respectively, first solder balls 39 and contacts 41. Substrate 33 includes interconnection pads 43 and 45 for similarly interconnecting first solder bumps 39 and contacts 41, respectively.

Unlike substrate 3 illustrated in FIGS. 3 and 4, substrate 33 illustrated in FIGS. 8a-8c does not include an upper surface having two different levels. At least the portion of the upper surface 34 of substrate 33 illustrated in FIGS. 8a-8c is arranged in one plane. While the first solder bumps and contacts in this embodiment may have similar sizes as in the embodiments illustrated in the other figures and described above, the interconnection pads 35 and 43 that interconnect the two substrates through the first solder bumps may be larger in this embodiment. By including larger interconnection pads, the first solder bumps may collapse to a greater degree than, for example, the first solder bumps in the embodiments illustrated in FIGS. 3-6, thereby permitting the substrates to approach each other more closely and accommodate the substrate without a stepped surface.

FIG. 8b illustrates a cross-sectional view of the embodiment illustrated in FIG. 8a as the solder reflow process starts. Accordingly, FIG. 8b illustrates first solder bumps 39 that have partially collapsed, bringing substrates 31 and 33 closer together and beginning to align the substrates. In FIG. 8c, the solder reflow process is complete, such that both first solder bumps 39 and contacts 41 have reflowed and are now joined to both substrate 31 and 33.

All of the various compositions, sizes and other parameters that the substrate, solder bumps, and contacts may be provided with may be substantially as described above. For example, if the contacts are made of solder, they may form second solder bumps. The second solder bumps may be reflow wherein the second solder bumps ball up to make contact between the first substrate and the second substrate. When the first solder bumps are reflowing, they may draw the first substrate toward the second substrate to cause the contacts to make contact with the first substrate and the second substrate.

The present invention also provides a method of fabricating the semiconductor structure. According to the method, a first substrate and a second substrate are provided. Contacts are provided on one of the first substrate and the second substrate. First solder bumps are provided on one of the first substrate and the second substrate. The first substrate and the second substrate are mounted on each other. And, the first solder bumps are reflowed for surface tension aligning of the contacts.

The present invention also includes a new method of making C4 interconnects utilizing a lift off stencil. Lift off stencil is a typical stencil utilized in thin film processing. Rather than a lift off stencil, a subtractive etch may also be utilized.

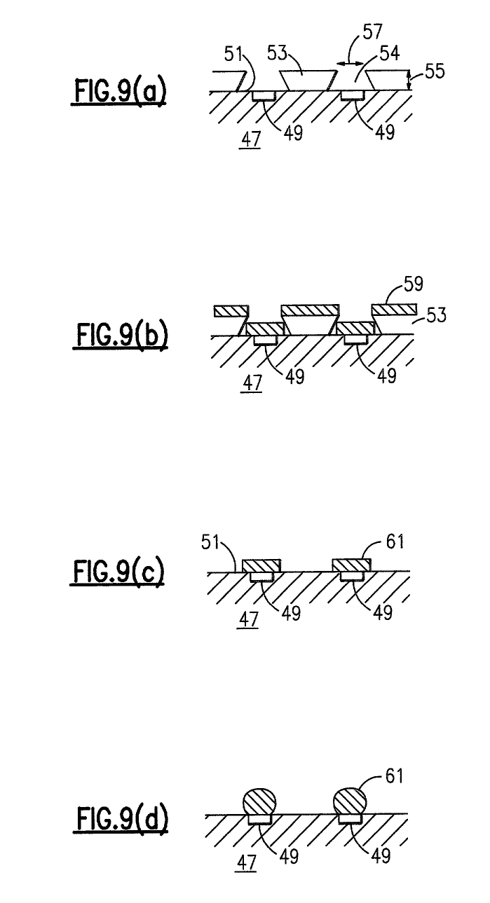

FIGS. 9a-9d illustrate structures at various stages of an embodiment of a process according to the present invention for forming contacts utilizing the lift off stencil. Along these lines, FIG. 9a illustrates a substrate 47 including contact pads 49 upon which contacts are to be formed. A layer of a photoresist has been deposited on the upper surface 51 of substrate 47. The photoresist has been exposed and developed leaving regions 53 of photoresist to form a mask or stencil for forming the contacts.

While the dimensions of the photoresist layer and the stencil may vary, depending upon the embodiment, according to one embodiment, the photoresist regions 53 have a thickness 55 of about 6 μm. The width of the openings 57 formed in the photoresist layer may be about 14 μm across. The openings 54 in the photoresist typically are aligned to the contact pads 49 in the substrate 47. Typically, the contact pads 49 are made of a metal and/or alloy.

After forming the stencil or mask to result in a structure illustrated in FIG. 9a, a material that will form the contacts may be deposited over the structure. According to one embodiment, a thin film of solder is evaporated onto the stencil or mask. FIG. 9b illustrates an example of an embodiment of the present invention wherein a thin film of solder has been evaporated onto the mask. The material deposited over the mask may be a material other than solder. Also, processes other than evaporation may be utilized to form the metal.

In any event, FIG. 9b illustrates regions of solder 59 deposited on the mask as well as any exposed regions of the substrate 47 and contact pads 49. The thickness of the solder or other material deposited on the mask may vary, depending upon the embodiment. According to one example, the material has a thickness of about 5 μm.

After depositing the material 59, the photoresist regions 53 forming the mask as well as any material deposited on top of the photoresist regions may be removed, leaving contacts 61 on the surface 51 of substrate 47. An example of such an structure is illustrated in cross section FIG. 9c. FIG. 9d illustrates the solder contact 61 after reflow.

The process described above and illustrated in FIGS. 9a-9d may also be utilized to form contacts of other materials, such as the materials described above.

The foregoing description of the invention illustrates and describes the present invention. Additionally, the disclosure shows and describes only the preferred embodiments of the invention, but as aforementioned, it is to be understood that the invention is capable of use in various other combinations, modifications, and environments and is capable of changes or modifications within the scope of the inventive concept as expressed herein, commensurate with the above teachings, and/or the skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

We claim:

1. A semiconductor structure, comprising:
a first substrate;
a second substrate joined to the first substrate;
a plurality of contacts between the first substrate and the second substrate; and
a plurality of first solder bumps connected between the first substrate and the second substrate for aligning the contacts.

2. The semiconductor structure according to claim 1, wherein the contacts have a different composition than the first solder bumps.

3. The semiconductor structure according to claim 1, wherein at least one of the first substrate and the second substrate is an integrated circuit chip.

4. The semiconductor structure according to claim 1, wherein the contacts comprise second solder bumps.

5. The semiconductor structure according to claim 4, wherein the second solder bumps have a smaller size than the first solder bumps.

6. The semiconductor structure according to claim 1, wherein the contacts have a smaller size than the first solder bumps.

7. The semiconductor structure according to claim 1, wherein the contacts comprise electrically conductive epoxy.

8. The semiconductor structure according to claim 1, wherein the contacts comprise a polymer-metal composite.

9. The semiconductor structure according to claim 1, wherein the contacts comprise at least one member selected from the group consisting of dendrites and self-interlocking micro connectors.

10. The semiconductor structure according to claim 1, wherein the contacts each have a diameter of less than about 50 μm.

11. The semiconductor structure according to claim 1, wherein the contacts each have a diameter of about 10 μm.

12. The semiconductor structure according to claim 1, wherein the contacts each have a diameter of less than about 10 μm.

13. The semiconductor structure according to claim 1, wherein the contacts have a pitch of less than about 100 μm.

14. The semiconductor structure according to claim 1, wherein the contacts have a pitch of about 30 μm.

15. The semiconductor structure according to claim 1, wherein the contacts have a diameter about 20 μ% of the diameter of the first solder bumps.

16. The semiconductor structure according to claim 1, wherein the contacts comprise a material having a higher melting point that the first solder bumps.

17. The semiconductor structure according to claim 1, wherein an upper surface of the contacts and an upper surface of the first solder bumps are co-planar.

18. The semiconductor structure according to claim 1, further comprising:
a ledge on at least one of the first substrate and the second substrate, wherein the first solder bumps are arranged in contact with the ledge, such that an upper surface of the contacts and an upper surface of the first solder bumps are co-planar.

19. The semiconductor structure according to claim 1, wherein the contacts comprise a material other than solder.

20. The semiconductor structure according to claim 1, wherein the contacts comprise solder.

21. The semiconductor structure according to claim 1, wherein the contacts comprise PMC.

22. The semiconductor structure according to claim 1, wherein the contacts provide optical communication between the first substrate and the second substrate.

23. The semiconductor structure according to claim 1, wherein the contacts comprise a waveguide.

24. The semiconductor structure according to claim 1, wherein the contacts comprise an optical transmitter and an optical receiver.

25. The semiconductor structure according to claim 1, wherein at least one of the first substrate and the second substrate is an integrated circuit chip, and the contacts are sufficiently small to permit alignment of individual devices on the integrated circuit chips.

26. A method of fabricating a semiconductor structure, the method comprising:
providing a first substrate and a second substrate;
providing contacts on one of the first substrate and the second substrate;
providing first solder bumps on one of the first substrate and the second substrate;
mounting the first substrate on the second substrate; and
reflowing the first solder bumps for surface tension aligning of the contacts.

27. The method according to claim 26, wherein the contacts have a different composition than the first solder bumps.

28. The method according to claim 26, wherein at least one of the first substrate and the second substrate is an integrated circuit chip.

29. The method according to claim 26, wherein the contacts comprise second solder bumps.

30. The method according to claim 29, further comprising:
reflowing the second solder bumps, wherein the second solder bumps ball up to make contact between the first substrate and the second substrate.

31. The method according to claim 29, wherein the second solder bumps comprise a material having a higher melting point that the first solder bumps, and reflowing the second solder bumps requires heating the second solder bumps to a higher temperature than reflowing the first solder bumps.

32. The method according to claim 29, wherein the second solder bumps are provided with a smaller size than the first solder bumps.

33. The method according to claim 26, wherein the contacts comprise electrically conductive epoxy.

34. The method according to claim 26, wherein the contacts comprise a polymer-metal composite.

35. The method according to claim 26, wherein reflowing the first solder bumps draws the first substrate toward the second substrate to cause the contacts to make contact with the first substrate and the second substrate.

36. The method according to claim 26, wherein the first solder bumps contact the first substrate and the second substrate prior to the contacts making contact between the first substrate and the second substrate.

37. The method according to claim 26, wherein the contacts are provided by thin film processing.

38. The method according to claim 37, wherein the thin film processing comprises lift off stencil or subtractive etch.

39. The method according to claim 26, wherein the contacts each are provided with a diameter of less than about 50 μm.

40. The method according to claim 26, wherein the contacts each are provided with a diameter of about 10 μm.

41. The method according to claim 26, wherein the contacts each are provided with a diameter of less than about 10 μm.

42. The method according to claim 26, wherein the contacts are provided with a pitch of less than about 100 μm.

43. The method according to claim 26, wherein the contacts are provided with a pitch of about 30 μm.

44. The method according to claim 26, wherein the contacts are provided with a diameter about 20% of the diameter of the first solder bumps.

45. The method according to claim 26, wherein the contacts are provided with a smaller size than the first solder bumps.

46. The method according to claim 26, wherein the contacts provide optical communication between the first substrate and the second substrate.

47. The method according to claim 26, wherein the contacts comprise a waveguide.

48. The method according to claim 26, wherein the contacts comprise an optical transmitter and an optical receiver.

49. The method according to claim 26, wherein the contacts comprise at least one member selected from the group consisting of dendrites and self-interlocking micro connectors.

50. The method according to claim 26, wherein the contacts and the first solder bumps are provided such that an upper surface of the contacts and an upper surface of the first solder bumps are co-planar.

51. The method according to claim 26, wherein the contacts comprise at least one member selected from the group consisting of solder, a material other than solder, and PMC.

52. The method according to claim 26, further comprising:
providing a ledge on at least one of the first substrate and the second substrate, wherein the first solder bumps are arranged in contact with the ledge, such that an upper surface of the contacts and an upper surface of the first solder bumps are co-planar.

53. The method according to claim 26, wherein the contacts are compressed as the first solder bumps are reflowed.
